(19) United States
(12) Patent Application Publication
(10) Pub. No.: US 2016/0295133 A1
(43) Pub. Date: Oct. 6, 2016

(54) CAMERAS HAVING A RGB-IR CHANNEL

(71) Applicant: Heptagon Micro Optics Pte. Ltd., Singapore (SG)

(72) Inventors: Hartmut Rudmann, Jona (CH); Peter Roentgen, Thalwil (CH)

(73) Assignee: Heptagon Micro Optics Pte. Ltd., Singapore (SG)

(21) Appl. No.: 15/082,776

(22) Filed: Mar. 28, 2016

Related U.S. Application Data
(60) Provisional application No. 62/143,333, filed on Apr. 6, 2015.

(51) Int. Cl. H04N 5/33; G06K 9/00; H04N 5/238; H04N 9/07

(52) U.S. Cl. CPC H04N 5/332; H04N 9/07; G06K 9/00255; G06K 9/00604; H04N 5/238

(57) ABSTRACT

The present disclosure describes various RGB-IR cameras, as well as new applications and methods of using such cameras. An apparatus includes an image sensor module including an image sensor. The image sensor has an active region including pixels operable to sense radiation in the visible and IR parts of the spectrum. The module can include, in some cases, a switchable IR filter disposed between the active region of the image sensor and an optical assembly. In various implementations, the module can be used in conjunction with one or more of the following: generating color images, generating IR images, performing iris recognition, performing facial recognition, and performing eye tracking/eye gazing.

### CROSS-REFERENCE TO RELATED APPLICATION(S)

The present applications claims the benefit of U.S. Provisional Patent Application No. 62/143,333 filed on Apr. 6, 2015. The contents of the earlier application are incorporated herein by reference in their entirety.

### FIELD OF THE DISCLOSURE

The present disclosure relates to cameras having an optical channel for sensing both color (RGB) and infra-red (IR) radiation.

### BACKGROUND

Recent developments in camera and sensor technologies, such as consumer-level photography, is the ability of sensors to record both IR and color (RGB). Various techniques can be provided for joint IR and color imaging. One approach is to swap color filters on a camera that is sensitive to IR. Another approach is to use one camera dedicated to IR imaging and another camera for color imaging. Using two cameras, however, can result in higher costs, larger overall footprint, and/or misalignment of the IR and color images.

### SUMMARY

The present disclosure describes various RGB-IR cameras, as well as new applications and methods of using such cameras.

For example, in one aspect, an apparatus includes an image sensor module. The module includes an image sensor that includes an active region. The active region includes pixels operable to sense radiation in a visible part of the spectrum and radiation in the IR part of the spectrum. The module further includes an optical assembly disposed over the active region of the image sensor, and a read-out circuit to acquire output signals from the pixels.

In some instances, the apparatus also includes an eye illumination source operable to emit modulated IR illumination toward a subject's face, and a depth sensor operable to detect optical signals indicative of distance to the subject's eye and to demodulate the detected optical signals. In some cases, the apparatus includes a diffuse IR illuminator operable to project IR light onto a subject's eye.

Depending on the implementation, processing circuitry processes output signals read from the sensor(s) to perform one or more of the following: (i) generate a color image based on the output signals from the pixels that sense color information in the visible part of the spectrum (i.e., RGB); (ii) generate an IR image based on the output signals from the pixels that sense IR information; (iii) perform iris recognition based on the output signals from the pixels that sense IR information; (iv) perform facial recognition based on the output signals from the pixels that sense color information in the visible part of the spectrum; (v) perform eye tracking/eye gazing based on depth data.

In some cases, providing both RGB and IR pixels in the same optical channel can be advantageous. For example, by using the same optical assembly for both the RGB and IR pixels, it can reduce the number of optical assemblies needed. Further, the overall footprint of the module can be reduced since separate channels are not needed for sensing the color and IR radiation.

In another aspect, an apparatus includes an image sensor module. The module includes an image sensor that includes an active region. The active region includes pixels, each of which is operable to sense radiation in the visible part of the spectrum and radiation in the IR part of the spectrum. The apparatus further includes an optical assembly disposed over the active region of the image sensor, and a switchable optical filter disposed between the active region of the image sensor and the optical assembly. The switchable optical filter is operable in a first state and in a second state. The first state allows radiation in the visible part of the spectrum and radiation in the IR part of the spectrum to pass from the optical assembly to the active region of the image sensor. The second state allows radiation in the visible part of the spectrum to pass from the optical assembly to the active region of the image sensor and substantially prevents radiation in the IR part of the spectrum from passing from the optical assembly to the active region of the image sensor.

Some implementations include one or more of the following features. For example, the switchable optical filter can include a mechanical shutter, an electro-wetting device, a MEMS tunable optical element, a movable liquid IR filter, and/or a Fabry-Perot filter.

Providing both the RGB and IR pixels in the same optical channel can be advantageous in some cases, because manufacturing costs can be reduced since the same optical assembly is used for both the RGB and IR pixels. Also, the overall footprint of the module can be reduced since separate channels are not needed for the RGB and IR sensing. By using all the pixels for sensing sequentially both RGB and IR radiation, higher resolution color and IR images can be acquired in some cases.

Other implementations will be readily apparent from the following detailed description, the accompanying drawings, and the claims.

### BRIEF DESCRIPTION OF THE DRAWINGS

FIG. 1 illustrates an example of an image sensor module.

FIG. 2 shows an example of part of an array of pixels.

FIG. 3 illustrates examples of other optoelectronic components that can be used with the image sensor module.

FIG. 4 illustrates another example of an image sensor module.

FIG. 5 shows another example of part of an array of pixels.

FIGS. 6A and 6B illustrate an example of a switchable IR filter.

### DETAILED DESCRIPTION

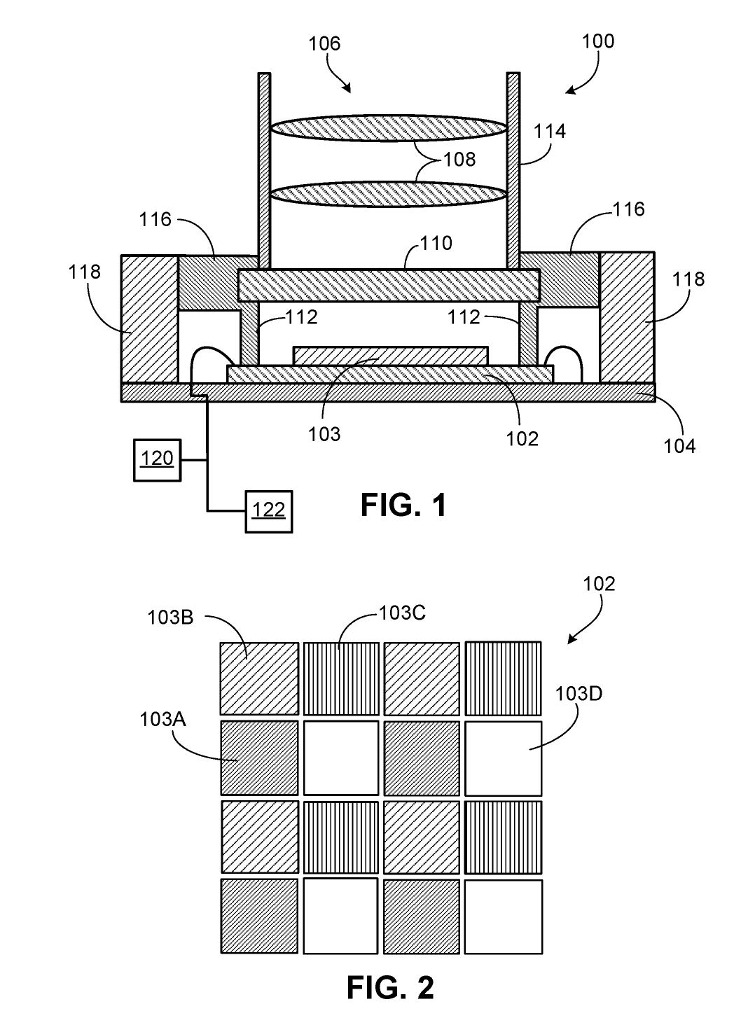

As illustrated in FIG. 1, a packaged image sensor module 100 can provide ultra-precise and stable packaging for an image sensor 102 mounted on a substrate 104 such as a printed circuit board (PCB). The image sensor 102 includes an array of sensitive elements (i.e., pixels) 103 each of which is sensitive to both color (e.g., RGB) and IR electromagnetic radiation (sometimes referred to as “light”). The image sensor 102 can be implemented, for example, as CCDs or photodiodes.

In the illustrated example, an optical assembly that includes a stack 106 of one or more optical beam shaping elements such as lenses 108 is disposed over the image sensor 102. The lenses 108 can be disposed, for example, within a lens barrel 114 that is supported, for example, by a transparent cover 110 (e.g., a cover glass), which in turn is supported by one or more vertical spacers 112 separating the image sensor 102 from the transparent cover 110. The vertical spacers 112 can be in direct contact (i.e., without adhesive) with non-active regions of the sensor 102. During fabrication of the module 100, the vertical spacers 112 can be machined, as needed, so as to adjust their height and thus achieve a precise pre-specified distance between the transparent cover 110 and the image sensor 102. Thus, the vertical spacers 112 can help establish a precisely defined distance between the light sensitive pixels 103 and the lens stack 106. In particular, the vertical spacers 112 can help establish a proper z-height such that the focal-length of the lenses 108 is on the image sensor 102. In some cases, the vertical spacers 112 can correct for tilt.

As illustrated in the example of FIG. 1, one or more horizontal spacers 116 laterally surround the transparent cover 110 and separate the outer walls 118 of the module housing from the transparent cover 110. The outer walls 118 can be attached, for example, by adhesive to the image sensor-side of the PCB 104. Adhesive also can be provided, for example, between the side edges of the cover 110 and the housing sidewalls 118. An example of a suitable adhesive is a UV-curable epoxy.

In some cases the cover 110 is composed of glass or another inorganic material such as sapphire that is transparent to wavelengths detectable by the image sensor 102. The vertical and horizontal spacers 112, 116 can be composed, for example, of a material that is substantially opaque for the wavelength(s) of light detectable by the image sensor 102. The spacers 112, 16 can be formed, for example, by a vacuum injection technique followed by curing. Embedding the side edges of the transparent cover 110 with the opaque material of the horizontal spacers 116 can be useful in preventing stray light from impinging on the image sensor 102. The outer walls 118 can be formed, for example, by a dam and fill process.

FIG. 2 shows a top view of a portion of the image sensor 102 according to some implementations. As illustrated, each pixel 103 is inherently sensitive to both RGB and IR radiation. Some of the pixels 103, however, have a color filter (e.g., red, green or blue) disposed over them. For example, pixel 103A has a red filter, pixel 103B has a green filter, and pixel 103C has a blue filter. Each of the color filters in this example allows light of the specified color (i.e., wavelength) to pass and be detected by the pixel, but blocks wavelengths associate with other colors as well as IR. On the other hand, pixel 103D has a filter (or no filter) that allows IR light to pass and be detected by the pixel. Although FIG. 2 shows a particular arrangement of pixels 103A-103D of an image sensor 102 for detecting RGB and IR light in a single optical channel, other arrangements are possible as well.

Providing both the RGB and IR pixels in the same optical channel can be advantageous. First, by using the same optical assembly for both the RGB and IR pixels, it can reduce the number of optical assemblies needed. Further, the overall footprint of the module can be reduced since separate channels are not needed for sensing the color and IR radiation.

A module 100 that includes an image sensor 102 having an array of pixels as shown in FIG. 2 and operable to detect both color and IR can be useful in a range of applications. A read-out circuit 120 and control/processing circuit 122, such as one or more microprocessor chips, can be coupled to the pixels 103 to control reading out and processing of the signals from the pixels (see FIG. 1). By using an arrangement that includes both RGB pixels and IR pixels, signals indicative of color intensity and signals indicative of IR intensity can be acquired at the same time in a single optical channel.

For example, in some cases, signals from the RGB pixels 103A-103C can be processed to obtain a color image (e.g., of a person), and signals from the IR pixels 103D can be processed to obtain an IR image.

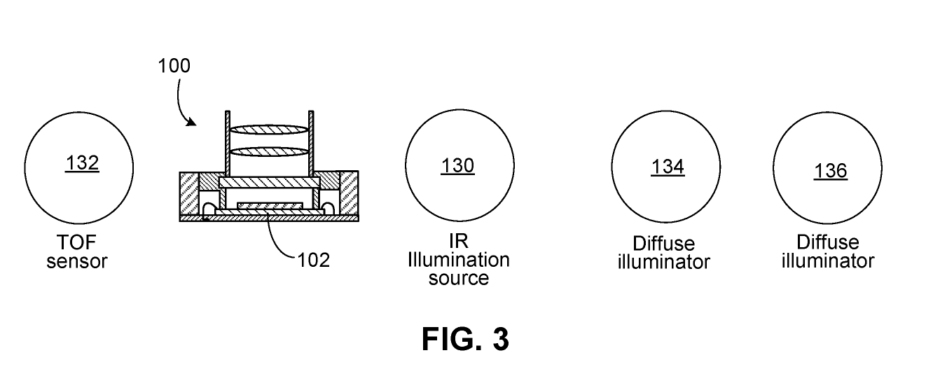

In some instances, signals from the RGB pixels 103A-103C can be processed to obtain a color image (e.g., of a person), and signals from the IR pixels 103D can be processed in accordance with an iris recognition protocol. Thus, the module 100 can be operable for iris recognition or other biometric identification. In such implementations, as shown in FIG. 3, an IR eye-illumination source 130, which can be integrated into the module 100 or separate from the module, is operable to emit light onto the iris of a user. Images of the user's iris can be captured using the IR pixels 103D of the image sensor 102. The images acquired by the sensor can be used as input into a pattern-recognition algorithm and/or other applications executed by the processing circuit 100 or other processor in a host device (e.g., a smart phone). Accordingly, the complex random patterns extracted from a user's iris or irises can be analyzed, for example, to identify the user. Affirmative identification of a user can, for example, be used to grant access of a host device to the user, and/or grant access to various applications or other software integrated into the host device (e.g., e-mail applications).

In some applications, iris recognition can be performed as follows. Upon imaging an iris, a 2D Gabor wavelet filters and maps the segments of the iris into phasors (vectors). These phasors include information on the orientation and spatial frequency and the position of these areas. This information is used to map the codes, which describe the iris patterns using phase information collected in the phasors. The phase is not affected by contrast, camera gain, or illumination levels. The phase characteristic of an iris can be described, for example, using 256 bytes of data using a polar coordinate system. The description of the iris also can include control bytes that are used to exclude eyelashes, reflection(s), and other unwanted data. To perform the recognition, two codes are compared. The difference between two codes (i.e. the Hamming Distance) is used as a test of statistical independence between the two codes. If the Hamming Distance indicates that less than one-third of the bytes in the codes are different, the code fails the test of statistical significance, indicating that the codes are from the same iris. Different techniques for iris algorithm can be used in other implementations.

Further in some implementations, the eye illumination source 130 is operable to emit modulated IR radiation (e.g., for time-of-flight (TOF)-based configurations). In such implementations, an optical time-of-flight (TOF) sensor 132 or other image sensor operable to detect a phase shift of IR radiation emitted by the eye illumination source can be provided either as part of the module 100 or as a component separate from the module. The modulated eye illumination source can include one or more modulated light emitters such as light-emitting diodes (LEDs) or vertical-cavity surface-emitting lasers (VCSELs).

In some cases, a diffuse IR illuminator 134 is provided either as part of the module 100 or separate from the module. The diffuse IR illuminator, which can include one or more light emitters such as light-emitting diodes (LEDs) or vertical-cavity surface-emitting lasers (VCSELs), is operable to project IR light onto the person's iris and can enhance the iris recognition protocol. For example, the eye's cornea is highly reflective (i.e., spectrally reflective), and thus the homogenous illumination from the illuminator reflects from the eye's cornea as a dot. The reflected dot is incident on, and sensed by, the IR pixels 103D of the image sensor 102 and/or the TOF sensor 132. Other parts of the subject's face are diffusively reflective, and thus are not as reflective as the subject's eye.

In some implementations, signals from the RGB pixels 103A-103C are processed in known fashion to obtain a color image (e.g., of a person's face), and signals from the IR pixels 103D are processed in accordance with a facial recognition protocol.

In some instances, iris recognition (based on signals from the IR pixels 103D) and facial recognition (based on signals from RGB pixels 103A-103C) can be combined with other applications, such as eye tracking or gaze tracking. Eye tracking refers to the process of determining eye movement and/or gaze point and is widely used, for example, in psychology and neuroscience, medical diagnosis, marketing, product and/or user interface design, and human-computer interactions. In such implementations, the eye illumination source 130 is operable to emit homogenous IR illumination toward a subject's face (including the subject's eye), and can be modulated, for example, at a relatively high frequency (e.g., 10-100 MHz). A depth sensor such as the TOF sensor 132 detects optical signals indicative of distance to the subject's eye, demodulates the acquired signals and generates depth data. Thus, in such implementations, the TOF sensor 132 can provide depth sensing capability for eye tracking. In such implementations, operations of both the image sensor 102 and TOF sensor 132 should be synchronized with the eye illumination source 130 such that their integration timings are correlated to the timing of the eye illumination source. Further, the optical axes of the eye illumination source 130 and the image sensor 102 (which includes the IR pixels 103D) should be positioned such that there is an angle between them of no less than about five degrees. Under such conditions, the pupil of the subject's eye appears as a black circle or ellipse in the image of the eye acquired by the IR pixels 103D. It also can help reduce the impact of specular reflections from spectacles or contact lenses worn by the subject.

In some implementations, two diffuse IR illuminators 134, 136 are provided, and an image of the eye is acquired by the IR pixels 103D of the image sensor 102. In this case, the reflected light forms a bright spot in the acquired image of the eye as a result of corneal reflection. If the subject's head is at a fixed pose, the direction of the subject's gaze can be determined by the vector formed between the center of corneal reflection and the center of pupil, which can be mapped to a target screen. Thus the coordinates of the gaze point can be determined using the horizontal and vertical components of the gaze direction and its distance from the subject's eye. Using two or more illuminators for eye tracking can be advantageous for several reasons. First, when there is head movement during eye tracking, the gaze direction is dependent on the head pose, in addition to the pupil center and corneal reflection. Multiple corneal reflections from the illuminators provides additional information from which head pose can be determined, and thus allow head movements during eye tracking.

The module 100, as well as the illumination sources 130, 134, 136 and depth sensor 132, can be mounted, for example, on the same or different PCBs within a host device. Depending on the implementation, the processing circuitry 122 processes output signals read from the sensor(s) to perform one or more of the following: (i) generate a color image based on the output signals from the pixels that sense color information in the visible part of the spectrum (i.e., RGB); (ii) generate an IR image based on the output signals from the pixels that sense IR information; (iii) perform iris recognition based on the output signals from the pixels that sense IR information; (iv) perform facial recognition based on the output signals from the pixels that sense color information in the visible part of the spectrum; (v) perform eye tracking/eye gazing based on depth data.

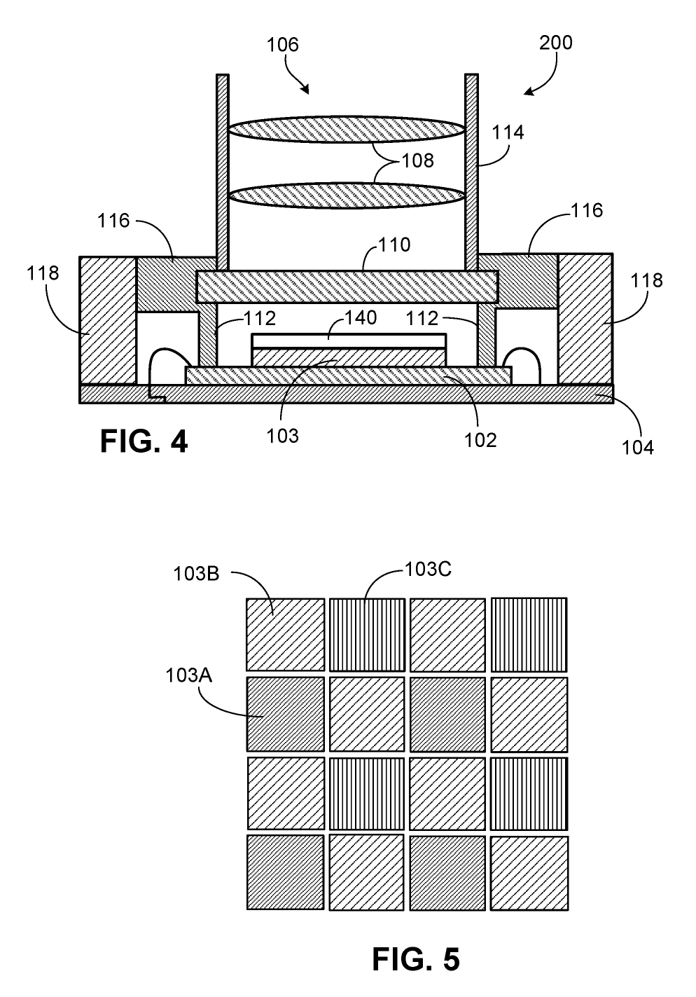

FIG. 4 illustrates an example of a module 200 that is similar to the module 100 of FIG. 1, but also includes a switchable IR filter 140 disposed between the pixels 103 of the image sensor 102 and the transparent cover 110. As indicated by FIG. 5, each pixel also has an associated color filter operable to pass light only of a specified color (e.g., red, green or blue). Thus, for example, some pixels 103A are operable to sense red light, some pixels 103B are operable to sense green light, and some pixels 103C are operable to sense blue light. In this case, however, each of the color filters over the pixels 103A-103C also allows IR radiation to pass.

The switchable IR filter 140 has a first state, which allows IR light to pass, and a second state, which blocks the IR light. When the filter 140 is in the first state, the pixels 103A-103C are able to sense IR radiation, which can be used, for example, for iris detection. However, when the filter 140 is in the second state, the pixels 103A-103C are able to sense only RGB light, whereas the IR radiation is blocked by the filter 140. The RGB signals from the pixels can be used, for example, to produce an RGB image.

Blocking the IR radiation while acquiring RGB output signals indicative of color can be advantageous because the IR radiation tends to cause interpixel cross-talk, which can degrade the color image. In operation, the processing circuit 122 controls the state of the switchable IR filter 140 so that the pixels alternately sense IR and IR/RGB.

As explained above, providing both the RGB and IR pixels in the same optical channel can be advantageous because manufacturing costs can be reduced since the same optical assembly is used for both the RGB and IR pixels. Also, the overall footprint of the module can be reduced since separate channels are not needed for the RGB and IR sensing. A further advantage of the implementation of FIGS. 4 and 5 is that all the pixels 103 in the array can be used for sensing RGB light and for sensing IR radiation. In some cases, this can achieve higher resolution images compared to the implementation of FIGS. 1 and 2, in which some pixels 103A-103C are used to sense RGB light and other pixels 103D are used to sense IR radiation. On the other hand, in the implementation of FIGS. 4 and 5, signals for the RGB light and signals for the IR radiation are obtained sequentially, rather than at the same time.

The switchable IR filter 140 can be implemented in any of a number of different ways. For example, in some cases, the switchable IR filter 140 is implemented as a mechanical shutter, whereas in other instances, it is implemented by an electro-wetting device or as a MEMS tunable optical element, in which a liquid IR filter is movable in and out of the optically active area. In yet other implementations, the switchable IR filter 140 includes a Fabry-Perot filter.

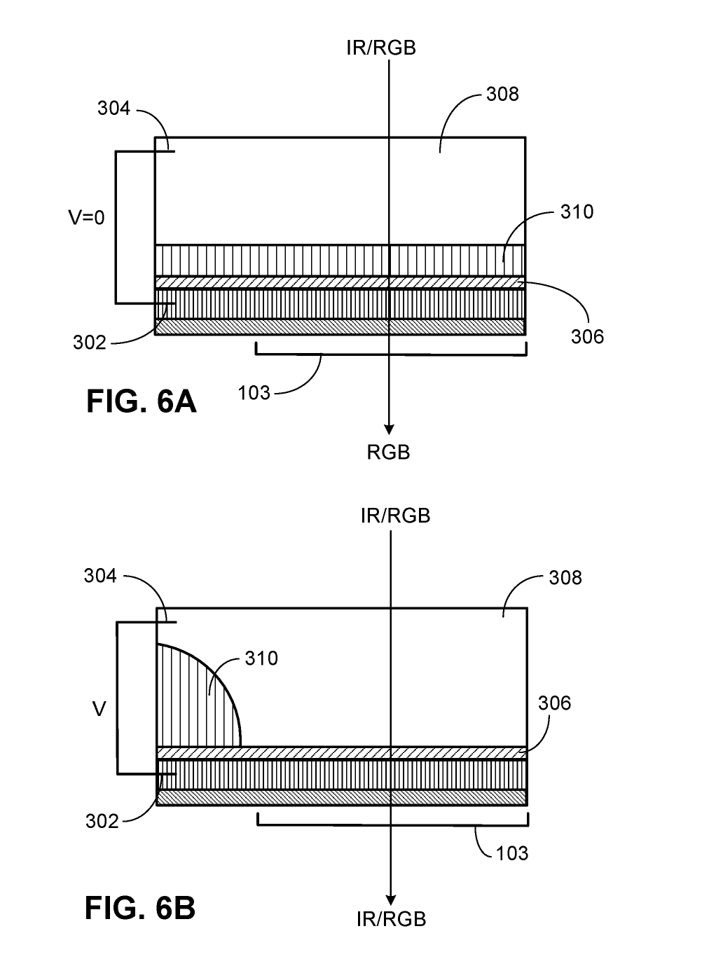

FIGS. 6A and 6B illustrate an example of the switchable IR filter 140 using electro-wetting. By applying a voltage, the wetting properties of a hydrophobic surface can be modified and the surface becomes increasingly hydrophilic (wettable). The modification of the surface tension is used to obtain a simple optical switch by contracting a colored oil film electrically. As shown in FIGS. 6A and 6B, a fluid chamber disposed over the active area 103 of the image sensor 102 has first and second electrodes 302, 304. A dielectric contact layer 306 is present on the first electrode 302. The fluid chamber contains first and second liquids 308, 310 that are immiscible. For example, the first liquid 308 can be water, which allows IR radiation to pass, and the second liquid 310 can be a colored oil film, which blocks or significantly attenuates IR radiation. When no voltage is applied across the electrodes 302, 304, the second liquid 310 is disposed in the chamber such that it prevents IR radiation from reaching the active area (i.e., the pixels 103) of the image sensor 102 (see FIG. 6A). On the other hand, when a voltage of sufficient magnitude is applied, the second liquid 310 contracts such that it no longer blocks IR radiation from reaching the active area of the sensor (see FIG. 6B).

The module 200 can be used in any of the applications discussed above, as well as other applications involving the sensing of RGB and IR. Thus, the module 200 also can be coupled to a read-out circuit 120 and processing circuit 122 as described above. The compact, small footprint cameras described here can be integrated, for example, into smart phones and other small mobile computing devices (e.g., tablets and personal data assistants (PDAs)).

Other implementations are within the scope of the claims.

What is claimed is:

1. An apparatus comprising:
an image sensor module including an image sensor that includes an active region, the active region including a plurality of pixels operable to sense radiation in a visible part of the spectrum and radiation in the IR part of the spectrum; and
an optical assembly disposed over the active region of the image sensor;
a read-out circuit to acquire output signals from the pixels; and
one or more processors to acquire the output signals, generate a color image based on the output signals from the pixels that sense color information in the visible part of the spectrum, and generate an IR image based on the output signals from the pixels that sense IR information.

2. An apparatus comprising:
an image sensor module including an image sensor that includes an active region, the active region including a plurality of pixels operable to sense radiation in a visible part of the spectrum and radiation in the IR part of the spectrum; and
an optical assembly disposed over the active region of the image sensor;
a read-out circuit to acquire output signals from the pixels; and
one or more processors configured to acquire the output signals, generate a color image based on the output signals from the pixels that sense color information in the visible part of the spectrum, and perform iris recognition based on the output signals from the pixels that sense IR information.

3. The apparatus of claim 2 further including an eye illumination source operable to illuminate a subject's eye with IR radiation.

4. The apparatus of claim 3 wherein the eye illumination source is operable to emit modulated IR radiation.

5. The apparatus of claim 2 further including a diffuse IR illuminator operable to project IR light onto a subject's eye.

6. An apparatus comprising:
an image sensor module including an image sensor that includes an active region, the active region including a plurality of pixels operable to sense radiation in a visible part of the spectrum and radiation in the IR part of the spectrum; and
an optical assembly disposed over the active region of the image sensor;
a read-out circuit to acquire output signals from the pixels; and
one or more processors to acquire the output signals, perform facial recognition based on the output signals from the pixels that sense color information in the visible part of the spectrum, and perform iris recognition based on the output signals from the pixels that sense IR information.

7. The apparatus of claim 6 further including:
an eye illumination source operable to emit modulated IR illumination toward a subject's face; and
a depth sensor operable to detect optical signals indicative of distance to the subject's eye and to demodulate the detected optical signals,
wherein the one or more processors are operable to generate depth data based on signals from the depth sensor.

8. The apparatus of claim 7 wherein the depth sensor includes an optical time-of-flight sensor.

9. The apparatus of claim 7 wherein the one or more processors are operable to perform eye tracking based on the depth data.

10. The apparatus of claim 6 further including a diffuse IR illuminator operable to project IR light onto a subject's eye.

11. An apparatus comprising:
an image sensor module including an image sensor that includes an active region, the active region including a plurality of pixels each of which is operable to sense radiation in the visible part of the spectrum and radiation in the IR part of the spectrum;
an optical assembly disposed over the active region of the image sensor;
a switchable optical filter disposed between the active region of the image sensor and the optical assembly, the switchable optical filter being operable in a first state and in a second state,
wherein the first state allows radiation in the visible part of the spectrum and radiation in the IR part of the spectrum to pass from the optical assembly to the active region of the image sensor; and
wherein the second state allows radiation in the visible part of the spectrum to pass from the optical assembly to the active region of the image sensor and substantially prevents radiation in the IR part of the spectrum from passing from the optical assembly to the active region of the image sensor.

12. The apparatus of claim 11 wherein the switchable optical filter includes a mechanical shutter.

13. The apparatus of claim 11 wherein the switchable optical filter includes an electro-wetting device.

14. The apparatus of claim 11 wherein the switchable optical filter includes a MEMS tunable optical element.

15. The apparatus of claim 11 wherein the switchable optical filter includes a movable liquid IR filter.

16. The apparatus of claim 15 wherein the movable liquid IR filter includes a colored oil film to block or significantly attenuate IR radiation.

17. The apparatus of claim 11 wherein the switchable optical filter includes a Fabry-Perot filter.

18. The apparatus of claim 11 further including a respective color filter disposed between the optical assembly and a particular one of the pixels, wherein each color filter is operable to pass radiation in the IR part of the spectrum and a particular portion of the visible part of the spectrum.

19. A method of using the apparatus of claim 11, the method including two or more of the following:
generating a color image based on output signals from the pixels sensing color radiation in the visible part of the spectrum when the switchable optical filter is in the second state; (ii) generating an IR image based on the output signals from the pixels sensing IR radiation when the switchable optical filter is in the first state; (iii) performing iris recognition based on output signals from the pixels sensing IR radiation when the switchable optical filter is in the first state; (iv) performing facial recognition based on output signals from the pixels sensing color radiation in the visible part of the spectrum when the switchable optical filter is in the second state.

20. The method of claim 19 wherein the method includes:
at least one of (i) or (iv); and
at least one of (ii) or (iii).
